(19) United States
(12) Patent Application Publication
(10) Pub. No.: US 2024/0282737 A1
(43) Pub. Date: Aug. 22, 2024

(54) FLUX, SUBSTRATE AND MANUFACTURING METHOD, AND DEVICE

(71) Applicants: BOE MLED Technology Co., Ltd., Beijing (CN); BOE TECHNOLOGY GROUP CO., LTD, Beijing (CN)

(72) Inventors: Liang Sun, Beijing (CN); Yutian Chu, Beijing (CN)

(73) Assignees: BOE MLED Technology Co., Ltd., Beijing (CN); BOE TECHNOLOGY GROUP CO., LTD., Beijing (CN)

(21) Appl. No.: 18/570,074

(22) PCT Filed: Jun. 22, 2021
(86) PCT No.: PCT/CN2021/101515

§ 371 Date: Dec. 14, 2023

(51) Int. Cl. H01L 23/00; B23K 35/36; B23K 35/362; H01L 25/075; H01L 33/62

(52) U.S. Cl. CPC H01L 24/13; B23K 35/3613; B23K 35/362; H01L 24/16; H01L 24/81; H01L 24/95; H01L 25/0753; H01L 33/62; H01L 2224/1132; H01L 2224/1145; H01L 2224/1329; H01L 2224/13311; H01L 2224/13313; H01L 2224/13339; H01L 2224/13347; H01L 2224/16238; H01L 2224/81005; H01L 2224/81192; H01L 2224/81815; H01L 2224/95001; H01L 2924/0132; H01L 2924/0133; H01L 2933/0066

(57) ABSTRACT

The present disclosure provides a flux, a substrate, a manufacturing method thereof, and a device. The flux includes a bulk material and a powdery conductive material mixed in the bulk material, and a volume ratio of the conductive material to the flux is 5% to 10%.

### TECHNICAL FIELD

The present disclosure relates to the field of soldering technology of electronic elements, in particular to a flux, a substrate, a manufacturing method thereof, and a device.

### BACKGROUND

An electronic element is bound to a substrate through heating the substrate in a reflow oven to melt a solder between a pad of the substrate and a pin of the electronic element after mounting the electronic element onto the pad.

### SUMMARY

An object of the present disclosure is to provide a flux, a substrate, a manufacturing method thereof, and a device, so as to improve the solderability between an electronic element and the substrate through the flux, and overcome such problems caused by the poor solderability of an existing flux as pseudo soldering, a high void ratio of a pad, and a low push-pull force of the solder with a small thickness.

In one aspect, the present disclosure provides in some embodiments a flux, including a bulk material and a powdery conductive material mixed in the bulk material. A volume ratio of the conductive material to the flux is 5% to 10%.

In a possible embodiment of the present disclosure, the conductive material includes at least one of a tin metal, a tin-silver alloy, a tin-silver-copper alloy, or a tin-bismuth alloy.

In a possible embodiment of the present disclosure, the flux has an adhesive force of 140 g to 180 g.

In a possible embodiment of the present disclosure, the flux has a viscosity of 160 Pa·s to 210 Pa·s.

In a possible embodiment of the present disclosure, the bulk material includes a rosin resin and derivatives thereof, a synthetic resin surfactant, an organic acid activator, a corrosion inhibitor, a co-solvent, and a film-forming agent.

In another aspect, the present disclosure provides in some embodiments a substrate, including: a base substrate, the base substrate including a plurality of pad groups; a plurality of electronic elements, the electronic element including pins; and a connection member arranged between a pad in the pad group and the pin and including the conductive material in the above-mentioned flux.

In a possible embodiment of the present disclosure, an orthogonal projection of the conductive material in the flux onto the base substrate substantially overlaps with an orthogonal projection of the pad in the pad group onto the base substrate.

In a possible embodiment of the present disclosure, the connection member further includes a tin-silver alloy or a tin-silver-copper alloy.

In yet another aspect, the present disclosure provides in some embodiments a device, including the above-mentioned substrate.

In still yet another aspect, the present disclosure provides in some embodiments a method for manufacturing the above-mentioned substrate, including: providing a base substrate including a plurality of pad groups; forming a plurality of electronic elements including pins; applying the above-mentioned flux onto pads in the plurality of pad groups; and mechanically soldering the pad with the corresponding pin.

In a possible embodiment of the present disclosure, the method further includes sputtering a solder onto the pin, and the solder is a tin-silver alloy or a tin-silver-copper alloy.

In a possible embodiment of the present disclosure, the applying the flux onto the pads in the plurality of pad groups specifically includes: plating a steel mesh having a plurality of openings onto the base substrate, the openings corresponding to the pads; and applying the flux into the plurality of openings of the steel mesh.

In a possible embodiment of the present disclosure, the mechanically soldering the pad with the corresponding pin :specifically includes: attaching the plurality of electronic elements to a thin film; mechanically transferring the plurality of electronic elements on the thin film to the base substrate, the pins of the electronic elements corresponding to the pads respectively; and soldering the pad with the corresponding pin through a reflow soldering process.

In a possible embodiment of the present disclosure, the thin film is an Ultra-violet (UV) membrane or a blue membrane.

In a possible embodiment of the present disclosure, when an opening size of the steel mesh is 40 μm to 90 μm, a particle size of the conductive material in the flux is 2 μm to 11 μm, and when the opening size of the steel mesh is greater than 90 μm, the particle size of the conductive material in the flux is 5 μm to 15 μm.

### BRIEF DESCRIPTION OF THE DRAWINGS

FIG. 1 is a schematic view showing a substrate according to one embodiment of the present disclosure;

FIG. 2 is a graph showing a printing effect of a flux including 2% to 5% by volume of a tin metal according to one embodiment of the present disclosure;

FIG. 3 is a graph showing a void effect of the flux including 2% and 5% by volume of a tin metal according to one embodiment of the present disclosure;

FIG. 4 is a graph showing a printing effect of the flux including 5% to 10% by volume of a tin metal according to one embodiment of the present disclosure;

FIG. 5 is a graph showing a void effect of the flux including 5% to 10% by volume of a tin metal according to one embodiment of the present disclosure;

FIG. 6 is a graph showing a printing effect of the flux including 15% to 40% by volume of a tin metal according to one embodiment of the present disclosure;

FIG. 7 is a graph showing a bridging effect of the flux including 15% to 40% by volume of a tin metal according to one embodiment of the present disclosure;

FIG. 8 is a schematic view showing a substrate according to one embodiment of the present disclosure;

FIG. 9 is a flow chart of a method for manufacturing the substrate according to one embodiment of the present disclosure;

FIG. 10 is another flow chart of the method for manufacturing the substrate according to one embodiment of the present disclosure; and

FIG. 11 is yet another flow chart of the method for manufacturing the substrate according to one embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments.

Shapes and sizes of thin layers in the drawings are for illustrative purposes only, but shall not be used to reflect any actual scale

In the related art, usually it takes the following steps to bind an electronic element to a substrate.

(1) The electronic element is moved to a correct position for releasing. It should be appreciated that, the electronic element may also be moved together with a growth substrate (which is made of e.g., sapphire, Si or SiC) or a carrier (a UV membrane or blue membrane).

(2) The electronic element is transferred from the original growth substrate or the carrier to a reception substrate through a mechanical force (such as punching), laser, van der Waals force, electromagnetic force, etc. The reception substrate is provided with a pad structure coupled to a pin of the electronic element. In this step, the pin of the electronic element is in contact with at least a part of a region of the pad structure.

(3) The pin of the electronic element is coupled to the pad on the reception substrate through reflow soldering or the like. To be specific, a solder is provided between the pin and the pad, and then heated and cured so as to achieve a firm electrical connection therebetween. It should be appreciated that the solder is provided on the pin of the electronic element or the pad on the Substrate prior to Step (2), and Step (3) is performed after Step (2) so as to achieve the firm electrical connection between the electronic element and the pad on the reception substrate.

In order to facilitate the soldering of the pin of the electronic element to the pad, usually a flux is used during the reflow soldering. As an accessory, the flux is mainly used to remove an oxide on a surface of the solder and a surface of a base metal, so as to ensure a desired surface cleanliness. In addition, it is able to prevent the surface from being oxidized again during the soldering through the flux, reduce a surface tension of the solder and improve the soldering performance. In some cases, when the electronic element is transferred from the original growth substrate or carrier to the reception substrate through punching, the flux is arranged on the pad of the reception substrate, so as to temporarily adhere the electronic element from the original growth substrate onto the corresponding pad. However, the flux evaporates dun the reflow soldering, and when there is an alignment error between the electronic element and the corresponding pad or when the solder on the pin of the electronic element has an insufficient thickness, such problems as pseudo soldering, a high void ratio of the pad, and a low push-pull force of the solder with a small thickness.

In order to solve the above-mentioned problems, the present disclosure provides in some embodiments a flux, which includes a bulk material and a conductive material mixed in the bulk material. A volume ratio of the conductive material to the flux is 5% to 10%.

According to the flux in the embodiments of the present disclosure, the conductive material having a volume ratio of 5% to 10% is mixed in the bulk material, so as to remarkably increase the solderability between a pin of an electronic element (e.g., a Mini/Micro LED) and a pad on a substrate, thereby to prevent the occurrence of such problem in an existing flux as pseudo soldering, a high void ratio of a pad, and a low push-pull force of a solder with a small thickness. In other words, through the flux in the embodiments of the present disclosure, it is able to remarkably increase the yield and the reliability of a product, reduce a thickness of the solder, and reduce the manufacture cost of the electronic element.

During the implementation, in the flux provided, the conductive material includes at least one of a tin metal, a tin-silver alloy, a tin-silver-copper alloy, or a tin-bismuth alloy.

Currently, a soldering processes generally includes applying a solder on one of the pin of the electronic element or the pad of the reception substrate, applying the flux on the pad of the reception substrate, placing the electronic element on corresponding pad of the reception substrate, and fixedly coupling the electronic element to the pad through reflow soldering.

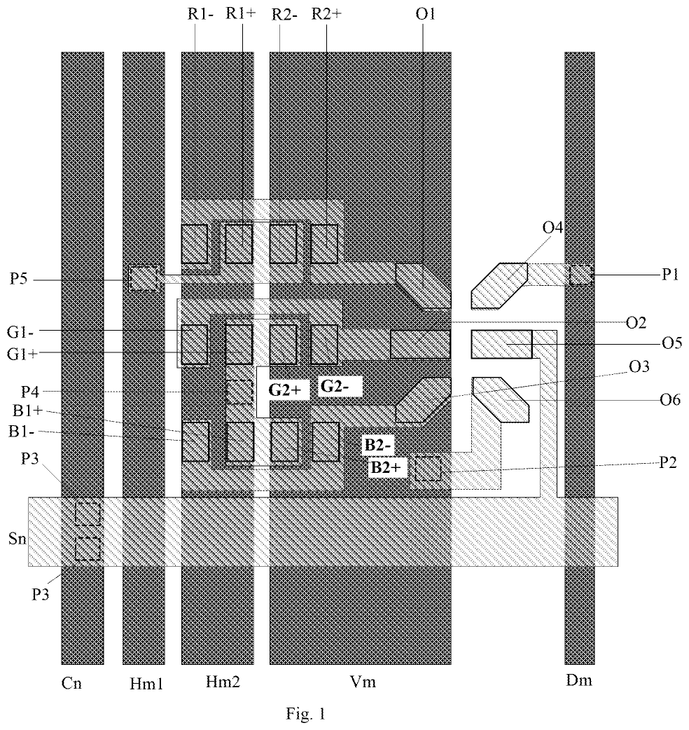

For example, as shown in FIG. 1, a first pad group to be bound to pins of some electronic elements (for example, a micro IC having 6 pins) and a second pad group to be bound to pins of some other electronic elements (for example, a mini/micro LED having 2 pins) are arranged on a substrate. The first pad group includes a sub-pad O1, a sub-pad O2, a sub-pad O3, a sub-pad O4, a sub-pad O5 and a sub-pad O6. The second pad group includes a sub-pad R1− and a sub-pad R1+ bound to positive and negative poles of a mini/micro LED in a first color respectively, a sub-pad R2− and a sub-pad R2+ bound to positive and negative poles of another mini/micro LED in the first color respectively, a sub-pad G1− and a sub-pad G1+ bound to positive and negative poles of a mini/micro LED in a second color respectively, a sub-pad G2− and a sub-pad G2+ bound to positive and negative poles of another color mini/micro LED in the second color respectively, a sub-paid B1− and a sub-pad B1+ bound to positive and. negative poles of a mien micro LED in a third color respectively, and a sub-pad B2− and a sub-paid B2+ bound to positive and negative poles of another mini/micro LED in the third color respectively.

During the implementation, as shown in FIG. 1, the sub-pad O2 on the substrate is coupled to the sub-pads G1− and G2− through a connection line, the sub-pad O3 is coupled to the sub-pads B1− and B2−through a connection line, the sub-pad O4 is coupled to a scanning line Cn through a transverse connection line Sn, the sub-pad O5 is coupled to a data signal line Dm through a via-hole P1, the sub-pad O6 is coupled to a reference signal line Vm through a via-hole P2, the sub-pads R1+ and R2+ are coupled to a first positive electrode signal line Hm1 through a via-hole P5, the sub-pads G1+ and G2+ are coupled to a second positive signal line Hm2 through a via-hole P4, and the sub-pads B1+ and B2+ are coupled to the second positive signal line Hm2 through a via-hole P4.

It should be appreciated that, the connection line between the sub-pads are located at a same film layer as the sub-pads. A protection layer is arranged above the connection line, but a surface of the sub-pad at a side away from the substrate needs to be exposed so as to be bound to the electronic element.

In addition, the connection line between the sub-pads is arranged at a layer different from any one of the scanning lure Cn, the data signal line Dm, the reference signal line Vm, the first positive electrode signal line Hm1 and the second positive electrode signal line Hm2, and no insulation layer is arranged therebetween, i.e., the two are electrically coupled to each other through a via-hole in the insulation layer.

The above is a repeating unit, and the substrate includes N*M repeating units, where 1≤n≤N and 1≤m≤M.

The soldering performance will be validated when a content of the conductive material in the flux, e.g.., a volume ratio of a tin metal to the flux (Vₜᵢₙ:Vₜₒₜₐₗ) is 2% to 40%. As shown in FIG. 1, when the substrate is provided with a first pad group (including 6 pads) bound to the pins of some electronic elements (e.g., a micro IC having 6 pins), the distribution of the tin metal in the flux is checked through a microscope and voids are checked through an X-ray device after the electronic element is firmly coupled to the pad.

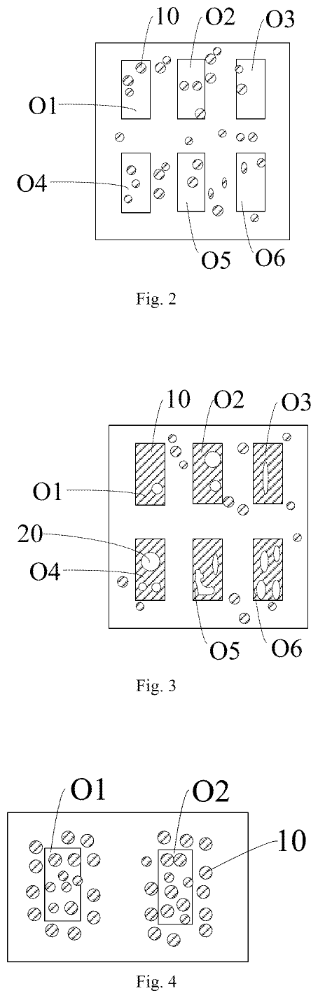

The volume ratio of the tin metal is 2% to 5%. FIG. 2 shows the distribution of the tin metal 10 applied onto the sub-pads O1 to O6 through sputtering. A check result obtained through the microscope shows that the content of the tin metal 10 on the sub-pads O1 to O6 is too low to ensure the uniform distribution of the tin metal 10 on each sub-pad. FIG. 3 shows the structure in FIG. 2 after the reflow soldering process. As shown in FIG. 3, there are voids 20 in the sub-pads O1 to O6 with a void rate of about 20%, and a pseudo-soldering rate is about 0.4%, so there is no improvement in the soldering performance as compared with a conventional flux.

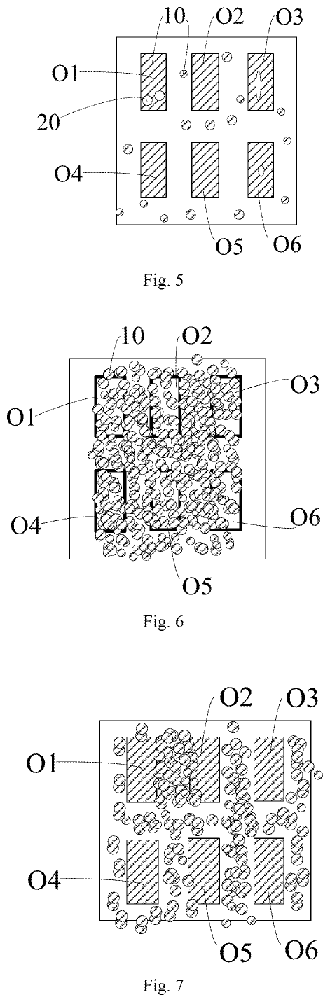

The volume ratio of the tin petal is 5% to 10%. FIG. 4 shows the distribution of the tin metal 10 applied onto the sub-pads O1 to O6 through sputtering. A check result obtained through the microscope shows that the content of the tin metal 10 is appropriate and meets a theoretical demand, and the tin metal 10 is uniformly distributed on the sub-pads O1 to O6 without any overlapping. FIG. 5 shows the structure in FIG. 4 after the reflow soldering process. As shown in FIG. 5, there are voids in the sub-pads O1 to O6 with a void rate of 5% to 10%, and the pseudo-soldering rate is 0.005%, so the soldering performance is improved remarkably as compared with the conventional flux.

The volume ratio of the tin metal is 15% to 40%. FIG. 6 shows the distribution of the tin metal 10 applied onto the sub-pads O1 to O6 through sputtering. A check result obtained through the microscope shows that the content of the tin metal 10 is larger than the theoretical demand, and the tin metal 10 is distributed on the sub-pads in an overlapping manner. FIG. 7 shows the structure in FIG. 6 after the reflow soldering process. As shown in FIG. 7, there are voids 20 in the sub-pads O1 to O6 with a void rate of 5% to 20%, the tin metal 10 is non-uniformly distributed between the sub-pads (e.g., between O1 and O2), and a bridging defect rate is about 0.2%. Due to an increase in the volume ratio of the tin metal 10, an adhesive property of the flux is adversely affected, i.e., the larger the volume ratio of the tin metal 10, the lower the adhesive property and the larger the soldering defect for the pin of the electronic element, so this scheme is infeasible.

Hence, in the final flux, the volume ratio of the tin metal to the flux is 5% to 10%, and a specific content of the tin metal is determined according to the practical need.

When a punching mode is used, the electronic element is removed off from the original growth substrate by means of an adhesive force of the flux, and then transferred onto the reception substrate, so the flux needs to be provided with the sufficient adhesive force to remove the electronic element off from the original growth substrate. The adhesive forces of different fluxes are tested through IPC-TM-650, Method 2.4.44, and a test result shows that the adhesive force of the flux needs to be 140g to 180g before the reflow soldering process. When the adhesive force si smaller than 140g, the soldering defect Occurs for the pin of the electronic element. Hence, in the embodiments of the present disclosure, the flux has an adhesive force of 140g to 180g.

During the implementation, the flux in the embodiments of the present disclosure has a viscosity of 106 Pa·S to 210 Pa·S according to IPC-TM-650, Method 2.4.44, so it is able to temporarily adhere the electronic element onto the corresponding pad.

During the implementation, the bulk material includes, but riot limited to, a rosin resin and derivatives thereof, a synthetic resin surfactant, an organic acid activator, a corrosion inhibitor, a co-solvent, and a film-forming agent.

It should be appreciated that, in order to uniformly mix the conductive material (e.g., tin metal) in the flux, it is necessary to stir the conductive material through a mixer for 5 minutes at a speed of 20 rpm at a normal temperature. Of course, the rotation speed and the rotation time may be adjusted according to the practical need.

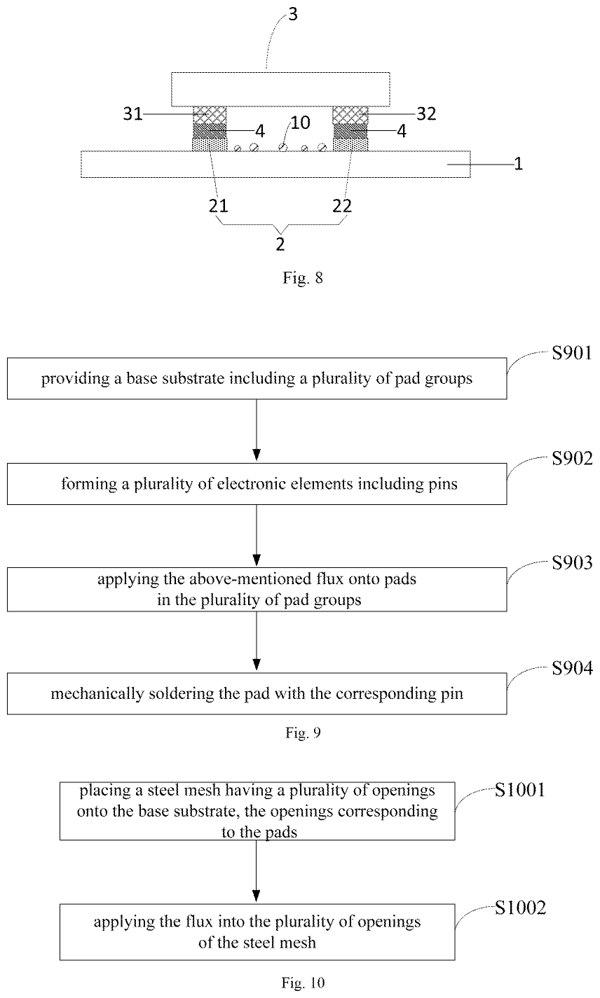

Based on a same inventive concept, the present disclosure further provides in some embodiments a substrate which, as shown in FIG. 8, includes: a base substrate 1, the base substrate 1 including a plurality of pad groups 2; a plurality of electronic elements 3, the electronic element 3 including pins 31 and 32; and a connection member 4 arranged between a pad in the pad group and the pin.

To be specific, the base substrate 1 is made of a rigid material such as glass, or a flexible material such as Polyimide. Each pad group 2 includes a first pad 21 and a second pad 22 arranged in pairs, and one pad group 2 is shown in FIG. 7 as an example.

To be specific, the electronic element 3 is a light-emitting element which includes a positive electrode pin 31 and a negative electrode pin 32. The quantity of pads in each pad group 2 is equal to the quantity of pins of one electronic element.

The connection member 4 is arranged between the first pad 21 and the positive electrode pin 31, and arranged between the second pad 22 and the negative electrode pin 32. The connection member 4 includes the conductive material in the above-mentioned flux.

During the manufacture of the substrate in the embodiments of the present disclosure, the above-mentioned flux is used so as to form the connection member with the solder in the reflow soldering. The flux includes 5% to 10% by volume of the conductive material, so it is able to remarkably increase the solderability between the pin of the electronic element and the pad on the substrate, and overcome such problems caused by the poor solderability of an existing flux as pseudo soldering, a high void ratio of the pad, and a low push-pull force of the solder with a small thickness. According to the substrate in the embodiments of the present disclosure, it is able to improve the yield and the reliability, reduce a thickness of the solder during the manufacture, and reduce the manufacture cost of the electronic element.

Along with the continuous development of the Light-Emitting Diode (LED) technology, a size of an LED decreases gradually. For example, the light-emitting element is a Mini LED, also called as Micro LED, i.e., an LED having a size of 80 μm to 300 μm. When the Mini LEDs are used as pixel points of a display panel to form a self-luminous display, as compared with a small-pitch LED display; it is able for the self-luminous display to provide a higher pixel density. When the Mini LEDs are used as light sources for a backlight module, it is able to provide an ultra-thin backlight module trough the Mini LEDs arranged in a denser manner, thereby to provide a display panel including the backlight module with a better contrast and a better high-dynamic-range rendering effect in combination with a region-based dimming technology. The micro LED having a size smaller than 80 μm may be directly used as a pixel point of a display panel for a near-to-eye, wearable or handle-held terminal

To be specific, when the electronic element is a light-emitting element, the base substrate 1 in FIG. 8 is, but not limited to, a substrate for providing a light source or a substrate for display.

During the implementation, as shown in FIG. 8, an orthogonal projection of the conductive material in the flux onto the base substrate 1 substantially overlaps with an orthogonal projection of the pad 21 or 22 in the pad group 2 onto the base substrate 1, so as to enable the pin to be electrically coupled to the pad. To be specific, a pattern of the flux n ay be adjusted according to the practical need.

During the implementation, when soldering the pin of the electronic element to the pad on the substrate, in order to enable the pin to be electrically coupled to the pad, a solder needs to applied onto the pin or pad for the subsequent reflow soldering. When the electronic element is transferred in a punching manner, usually the solder is applied onto the pin of the electronic element, and the solder is a tin-silver alloy or a tin-solver-copper alloy. Hence, in the embodiments of the present disclosure, as shown in FIG. 8, the connection member 4 further includes a tin-silver alloy or a tin-silver-copper alloy. To be specific, a ratio of metals in the tin-silver alloy or tin-silver-copper alloy may be adjusted according to the practical need.

Based on a same inventive concept, the present disclosure further provides in some embodiments a method for manufacturing the above-mentioned substrate which, as shown in FIG. 9, includes: S901 of providing a base substrate including a plurality of pad groups; S902 of forming a plurality of electronic elements including pins; S903 of applying the above-mentioned flux onto pads in the plurality of pad groups; and S904 of mechanically soldering the pad with the corresponding pin.

According to the method in the embodiments of the present disclosure, the flux is applied onto the pads in the plurality of pad groups, and during the soldering, the conductive material in the flux, e.g., the tin metal, is reserved as a part of the connection member between the pin and the pad. As compared with the related art where the flux almost completely evaporates, in the embodiments of the present disclosure, it is able to remarkably increase the solderability between the pin of the electronic element (e.g., a light-emitting element) and the pad on the substrate, thereby to overcome such problems caused by the poor solderability of an existing flux as pseudo soldering, a high void ratio of a pad, and a low push-pull force of the solder with a small thickness.

During the implementation, the method further includes sputtering a solder onto the pin. The solder is in contact with the flux dining the soldering, and apart from the tin metal, the bulk material of the flux evaporates, so that the tin metal and the solder form the connection member between the pin and the pad. The solder is a tin-silver alloy or a tin-silver-copper.

During the implementation, as shown in FIG. 10, the applying the flux onto the pads in the plurality of pad groups specifically includes: S1001 of placing a steel mesh having a plurality of openings onto the base substrate, the openings corresponding to the pads; and S1002 of applying the flux into the plurality of openings of the steel mesh.

To be specific, the openings correspond to the pads respectively, or each opening corresponds to a plurality of pads, which may be adjusted according to the practical need.

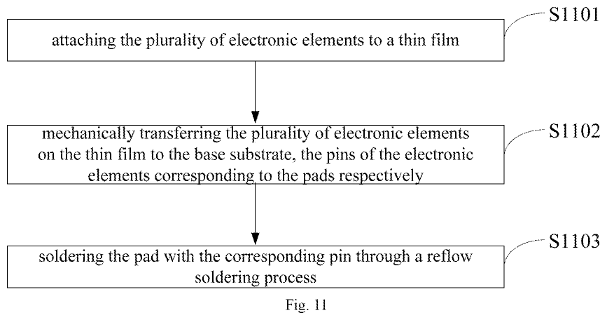

During the implementation, as shown in FIG. 11, the mechanically soldering the pad with the corresponding pin specifically includes the following steps.

S1101: attaching the plurality of electronic elements to a thin film.

To be specific, the electronic element is a light-emitting element, and the thin film is a UV membrane or a blue membrane.

S1102: mechanically transferring the plurality of electronic elements on the thin film to the base substrate, the pins of the electronic elements corresponding to the pads respectively.

S1103: soldering the pad with the corresponding pin through a reflow soldering process.

During the implementation, when an opening size of the steel mesh in S901 is 40 μm to 90 μm, a particle size of the conductive material in the flux is 2 μm to 11 μm, or when the opening size of the steel mesh in S901 is greater than 90 μm, the particle size of the conductive material in the flux is 5 μm to 15 μm.

It should be appreciated that, in the embodiments of the present disclosure, the soldering process of the pin with the pad has been described hereinabove when the electronic element is a light-emitting element (e.g., LED), i.e., the flux is used for the soldering, process at a light-emitting region. Of course, the flux in the embodiments of the present disclosure may also be used for an element, e.g., a sensor, at a peripheral region.

Based on a same inventive concept, the present disclosure further provides in some embodiments a display device, which includes the above-mentioned substrate.

The display device is a rigid display device or a flexible display device (i.e., a bendable or foldable display device). The display device may be any product or member having a display function such as mobile phone, tablet computer, television, display, notebook computer, digital photo frame or navigator. The other essential components of the display device are known in the art and are not described in detail herein and thus will not be particularly defined herein. The principle of the display device for solving the problem is similar to that of the above-mentioned substrate, and the implementation of the display device may refer to that of the substrate, which will not be particularly defined herein.

According to the flux, the substrate, the manufacturing method thereof and the device in the embodiments of the present disclosure, the conductive material having a volume ratio of 5% to 10% is mixed in the bulk material, so as to remarkably increase the solderability between the pin of the electronic element (e.g., a light-emitting element) and the pad on the substrate, thereby to prevent the occurrence of such problem in an existing flux as pseudo soldering, a high void ratio of a pad, and a low push-pull force of a solder with a small thickness. In other words, through the flux in the embodiments of the present disclosure, it is able to remarkably increase the yield and the reliability of a product, reduce a thickness of the solder, and reduce the manufacture cost of the electronic element.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A flux, comprising a bulk material and a powdery conductive material mixed in the bulk material, wherein a volume ratio of the conductive material to the flux is 5% to 10%.

2. The flux according to claim 1, wherein the conductive material comprises at least one of a tin metal, a tin-silver alloy, a tin-silver-copper alloy, or a tin-bismuth alloy.

3. The flux according to claim 1, wherein the flux has an adhesive force of 140 g to 180 g.

4. The flux according to claim 1, wherein the flux has a viscosity of 160 Pa·s to 210 Pa·s.

5. The flux according to claim 1, wherein the bulk material comprises a rosin resin and derivatives thereof, a synthetic resin surfactant, an organic acid activator, a corrosion inhibitor, a co-solvent, and a film-forming agent.

6. A substrate, comprising:
a base substrate, the base substrate comprising a plurality of pad groups;
a plurality of electronic elements, the electronic element comprising pins; and
a connection member arranged between a pad in the pad group and the pin and comprising the conductive material in a flux,
wherein the flux comprises a bulk material and the conductive material mixed in the bulk material, and a volume ratio of the conductive material to the flux is 5% to 10%.

7. The substrate according to claim 6, wherein an orthogonal projection of the conductive material in the flux onto the base substrate substantially overlaps with an orthogonal projection of the pad in the pad group onto the base substrate.

8. The substrate according to claim 6, wherein the connection member further comprises a tin-silver alloy or a tin-silver-copper alloy.

9. A device, comprising the substrate according to claim 6.

10. A method for manufacturing the substrate according to claim 6, comprising:
providing a base substrate comprising a plurality of pad groups;
forming a plurality of electronic elements comprising pins;
applying a flux onto pads in the plurality of pad groups; and
mechanically soldering the pad with the corresponding pin,
wherein the flux comprises a bulk material and the conductive material mixed in the bulk material, and a volume ratio of the conductive material to the flux is 5% to 10%.

11. The method according to claim 10, further comprising sputtering a solder onto the pin, wherein the solder is a tin-silver alloy or a tin-silver-copper alloy.

12. The method according to claim 10, wherein the applying the flux onto the pads in the plurality of pad groups specifically comprises:
placing a steel mesh having a plurality of openings onto the base substrate, the openings corresponding to the pads; and
applying the flux into the plurality of openings of the steel mesh.

13. The method according to claim 10, wherein the mechanically soldering the pact with the corresponding pin specifically comprises:
attaching the plurality of electronic elements to a thin film;
mechanically transferring the plurality of electronic elements on the thin film to the base substrate, the pins of the electronic elements corresponding to the pads respectively; and
soldering the pad with the corresponding pin through a reflow soldering process.

14. The method according to claim 13, wherein the thin film is an Ultra-violet (UV) membrane or a blue membrane.

15. The method according to claim 12, wherein an opening size of the steel mesh is 40 μm to 90 μm, a particle size of the conductive material in the flux is 2 μm to 11 μm, and when the opening size of the steel mesh is greater than 90 μm, the particle size of the conductive material in the flax is 5 μm to 15 μm.

16. The substrate according to claim 6, wherein the conductive material comprises at least one of a tin metal, a tin-silver alloy, a tin-silver-col per alloy, or a tin-bismuth 140 g to 180 g.

17. The substrate according to claim 6, wherein the flux has an adhesive force of 140 g to 180 g.

18. The substrate according to claim 6, wherein the flux has a viscosity of 160 Pa·s to 210 Pa·s.

19. The substrate according to claim 6, wherein the bulk material comprises a rosin resin and derivatives thereof, a synthetic resin surfactant, an organic acid activator, a corrosion inhibitor, a co-solvent, and a film-forming agent.

20. The device according to claim 9, wherein the conductive material comprises at least one of a tin metal, a tin-silver alloy, a tin-silver-copper alloy or a tin-bismuth alloy.
